(19) United States
(12) Patent Application Publication
(10) Pub. No.: US 2026/0114174 A1
(43) Pub. Date: Apr. 23, 2026

(54) DISPLAY DEVICE

(71) Applicant: LG Display Co., Ltd., Seoul (KR)

(72) Inventors: Sung Gon HONG, Paju-si (KR); Chang Heon KANG, Paju-si (KR); Jong Chan PARK, Paju-si (KR)

(73) Assignee: LG Display Co., Ltd., Seoul (KR)

(21) Appl. No.: 19/314,653

(22) Filed: Aug. 29, 2025

(30) Foreign Application Priority Data
Oct. 21, 2024 (KR) 10-2024-0143767

(51) Int. Cl. H10K 77/10; H10K 59/127; H10K 59/131; H10K 59/80

(52) U.S. Cl. CPC H10K 77/111; H10K 59/127; H10K 59/131; H10K 59/873

(57) ABSTRACT

A display device can include a substrate having a display area and a non-display area and including a first flexible substrate, an interlayer, and a second flexible substrate. The display device can further include a transistor and a light emitting device in the display area, and a driving chip in the non-display area. Also, the interlayer can be disposed between the first flexible substrate and the second flexible substrate without overlapping with an edge portion of at least one side of the driving chip.

### CROSS-REFERENCE TO RELATED APPLICATIONS

This application claims priority to Korean Patent Application No. 10-2024-0143767, filed in the Republic of Korea on Oct. 21, 2024, the entirety of which is hereby incorporated by reference into the present application as if fully set forth herein.

### BACKGROUND

### FIELD OF THE DISCLOSURE

The present disclosure relates to a display device, and more particularly, to a display device capable of improving reliability.

### Discussion of the Related Art

Display devices that display images, such as TVs, monitors, smartphones, tablets, and laptops, are used in various ways and forms.

A display device includes a display panel having a plurality of light emitting devices or liquid crystals for displaying an image and transistors for controlling the operation of each light emitting device or liquid crystal, to display an image as desired through the light emitting devices or liquid crystals.

A self-emissive organic light emitting display device is thinner than a display device with a separate light source embedded therein and obviates the need for a separate light source (e.g., no backlight needed), enabling the manufacture of display devices that are bendable or have various designs.

With the advent of the information age, the field of display devices that visually display electrical information signals is rapidly developing, and research is ongoing to develop performance metrics such as slimness, low power consumption, or high reliability for various display devices.

However, display devices often have a complex layered structure and integrating components such as driving chips can present significant challenges. For example, issues can occur at the interface where a driving chip is mounted onto the flexible substrate. Further, stresses induced during manufacturing and daily use can lead to the formation of micro-cracks in the various layers of the display panel, which can create pathways for moisture and other contaminants to penetrate the sensitive internal components.

Also, regarding the area around a driving chip, accumulated or stored electrical charges can flow into the driving chip, which can cause a gradual deterioration in its performance. Also, physical defects such as film lifting and panel deformation can reduce the durability of the display device.

Accordingly, a need exists for a display device have a configuration that can mitigate or prevent these types of issues by preventing charge inflow to the driving chip, minimizing the formation of cracks, and reducing film delamination, in order to improve the reliability and lifespan of the device.

### SUMMARY OF THE DISCLOSURE

An object of the present disclosure is to provide a display device that prevents charge inflow into a driving chip and prevents deterioration in reliability of the driving chip due to accumulated or stored charges in the display device.

Another object of the present disclosure is to provide a display device having improved reliability by minimizing cracking and preventing crack propagation and moisture penetration.

Still another object of the present disclosure is to provide a display device having improved robustness and durability by reducing film lifting defects and deformation of a display panel.

Yet another object of the present disclosure is to provide a display device in which the same process can be utilized, occurrence of defects in the display device can be minimized, reducing energy consumed to produce the display device, and the use of hazardous production materials or regulated materials can be reduced, facilitating recycling and implementation of an eco-friendly display device.

An embodiment of the present disclosure provides a display device including a substrate having a display area and a non-display area and including a first flexible substrate, an interlayer, and a second flexible substrate, a transistor and a light emitting device at the display area, and a driving chip at the non-display area, in which the interlayer is disposed between the first flexible substrate and the second flexible substrate and is disposed so as not to overlap an edge portion of at least one side of the driving chip at the non-display area.

The interlayer can be disposed inside the substrate without overlapping with the four sides of the lower surface of the driving chip.

The display device according to an embodiment of the present disclosure can further include a pad disposed on the substrate at an area where the driving chip is disposed, and a bump disposed under the driving chip corresponding to the pad. The interlayer can be disposed so that is does not overlap with an area between an edge of at least one side of the driving chip and an outermost pad among a plurality of pads. Or the interlayer can be disposed so that is does not overlap with an area between an edge of at least one side of the driving chip and an outermost bump among a plurality of bumps.

The interlayer can include a plurality of interlayer patterns disposed between the first flexible substrate and the second flexible substrate at an area where the driving chip is mounted.

The interlayer patterns can be disposed between the first flexible substrate and the second flexible substrate to overlap with a plurality of bumps of the driving chip and not overlap gaps between the bumps.

The interlayer patterns can be disposed between the first flexible substrate and the second flexible substrate to overlap with a plurality of pads disposed on the substrate corresponding to the driving chip and not overlap with gaps between the pads.

The interlayer or the interlayer patterns can include silicon oxide.

Another embodiment of the present disclosure provides a display device including a substrate having a display area and a non-display area and including a first flexible substrate, an interlayer, and a second flexible substrate, a transistor and a light emitting device disposed at the display area, and a driving chip disposed at the non-display area, in which the interlayer is disposed between the first flexible substrate and the second flexible substrate and is disposed so as not to overlap an edge portion of at least one side of the driving chip at the non-display area, and the display device further includes an insulating film disposed by stacking a plurality of layers at the non-display area of the substrate, an anisotropic conductive film disposed between the driving chip and the insulating film, and a plurality of crack prevention patterns spaced apart from the driving chip and the anisotropic conductive film and disposed on the insulating film.

The crack prevention patterns can be provided in the form of a relief pattern including metal.

The crack prevention patterns can include the same material as the source/drain electrode or the gate electrode constituting the transistor at the display area.

The crack prevention patterns can be disposed on the same layer as the pad disposed on the substrate or can include the same material as the pad.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plan view of a display device according to an embodiment of the present disclosure;

FIG. 2 is a plan view of the display panel of FIG. 1 in an unfolded state before a bending process according to an embodiment of the present disclosure;

FIG. 3 is a circuit diagram of a sub-pixel according to an embodiment of the present disclosure;

FIG. 4 is a cross-sectional view of a sub-pixel according to an embodiment of the present disclosure;

FIG. 5 is an enlarged partial plan view of portion A of FIG. 2 an embodiment of the present disclosure;

FIG. 6 is a cross-sectional view taken along line I-I′ of FIG. 5 according to an embodiment of the present disclosure;

FIG. 7 is a cross-sectional view taken along line II-II′ of FIG. 5 according to an embodiment of the present disclosure;

FIG. 8 is a cross-sectional view taken along line I-I′ of FIG. 5 according to another embodiment of the present disclosure;

FIG. 9 is a cross-sectional view taken along line II-II′ of FIG. 5 according to another embodiment of the present disclosure;

FIG. 10 is an enlarged partial plan view of portion A of FIG. 2 according to another embodiment of the present disclosure; and

FIG. 11 is a cross-sectional view taken along line III-III′ of FIG. 10 according to an embodiment of the present disclosure.

### DETAILED DESCRIPTION OF THE EMBODIMENTS

Hereinafter, embodiments will be described with reference to the drawings.

The same reference numerals indicate the same components. Also, in the drawings, the thickness, ratio, and dimensions of components can be exaggerated for effective explanation of the technical contents. The scale of the components depicted in the drawings is different from the actual scale for convenience of explanation, and the present disclosure is not limited to the scale depicted in the drawings.

Herein, when a component (or region, layer, portion, etc.) is referred to as being “on,” “connected,” or “coupled” to another component, it means that it can be directly connected/coupled to the other component, or a third component can be interposed therebetween.

“And/or” includes any combination of one or more of the associated components that can be defined.

The terms such as first, second, etc. can be used to describe various components, but are not to be construed as limiting the components. These terms are used only for the purpose of distinguishing one component from another. For example, without departing from the scope of the present embodiments, a first component could be referred to as a second component, and similarly, a second component could also be referred to as a first component. The singular expression includes the plural expression unless the context clearly dictates otherwise.

The terms “below,” “beneath,” “lower,” “above,” “upper,” and the like are used to describe the relationships between components depicted in the drawings. These terms are relative concepts and are explained based on the direction indicated in the drawings. For example, there can be one or more other portions located between two parts, unless “just” or “directly” is used. The spatially relative terms “below,” “beneath,” “lower,” “above,” “upper,” and the like can be used to easily describe the relationship of one element or component to another, as depicted in the drawings. The spatially relative terms should be understood to include different directions of the element when in use or operation in addition to the direction indicated in the drawings. For example, when elements depicted in a drawing are flipped, an element described as “below” or “beneath” another element can end up being disposed “above” the other element. Thus, the example term “below” or “beneath” can include both downward and upward directions.

It should be understood that the terms “include” or “have,” etc. are intended to specify the presence of a feature, number, step, operation, component, part, or combination thereof described herein, but do not exclude in advance the possibility of the presence or addition of one or more other features, numbers, steps, operations, components, parts, or combinations thereof.

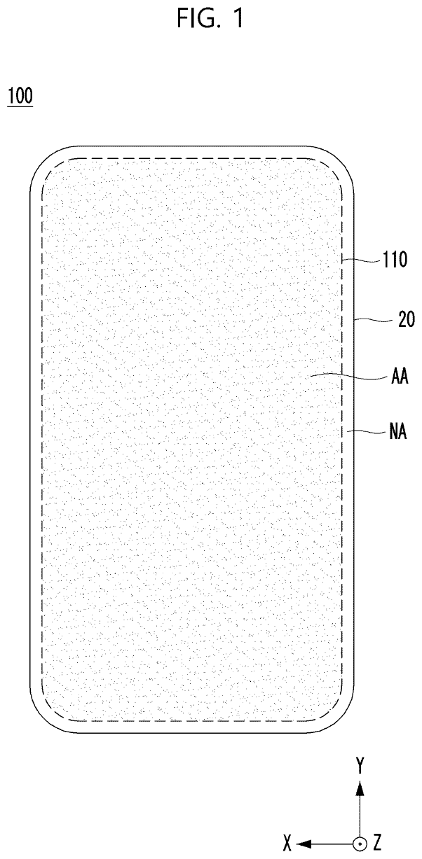

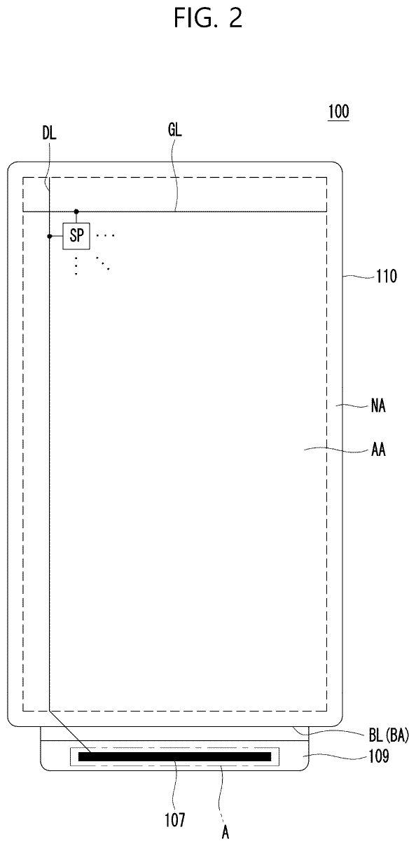

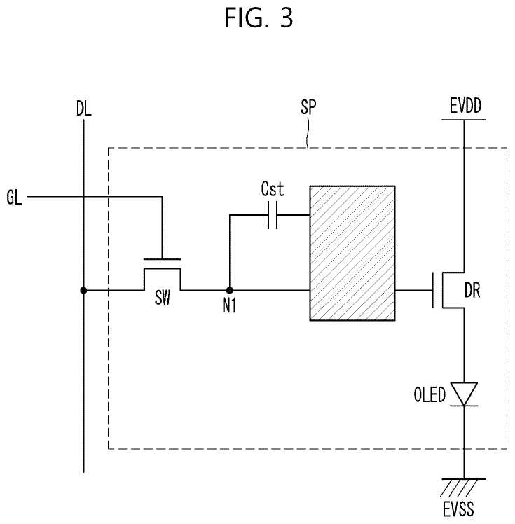

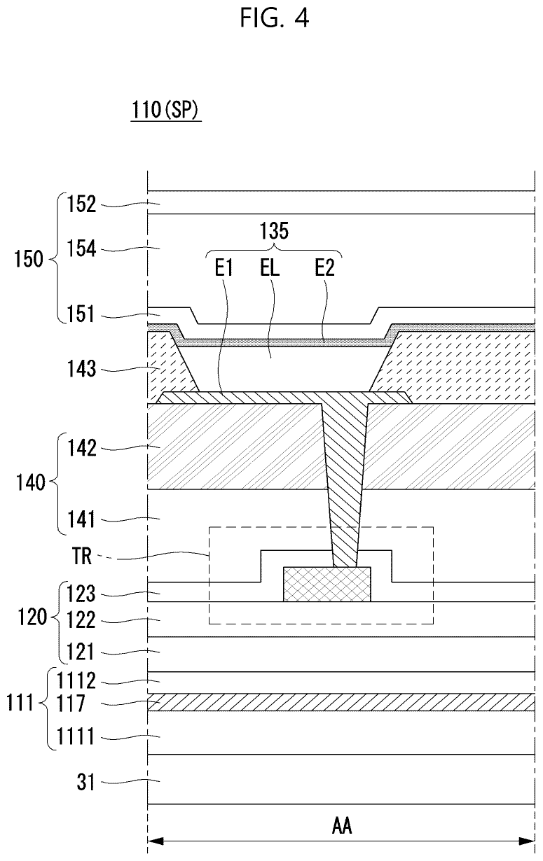

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship. Also, the term “can” used herein includes all meanings and definitions of the term “may.”Hereinafter, a detailed description will be given of a display device of the present disclosure with reference to the attached drawings and embodiments. FIG. 1 is a plan view of a display device according to an embodiment of the present disclosure, FIG. 2 is a plan view of the display panel of FIG. 1 in an unfolded state according to an embodiment of the present disclosure, FIG. 3 is a circuit diagram of a sub-pixel according to an embodiment of the present disclosure, and FIG. 4 is a cross-sectional view of a sub-pixel according to an embodiment of the present disclosure.

Referring to FIGS. 1 and 2, a display device 100 according to an embodiment of the present disclosure includes a display panel 110 including a display area AA and a non-display area NA, a light emitting device 135 (e.g., FIG. 4) disposed at the display area AA, and a driving chip 107 disposed at the non-display area NA of the display panel 110. The driving chip 107 can be disposed at a driving circuit area 109 beyond a bending area BA including a bending line BL at the non-display area NA. For example, the driving chip 107 can be a data driving circuit or data driver, but embodiments are not limited thereto. According to an embodiment, driving chip 107 can be part of a gate driver, a touch controller, a timing controller, a power management circuit, etc. The display device 100 further includes a cover member 20 disposed on the display panel 110.

The cover member 20 can be disposed on the top of the display panel 110 to cover the front surface of the display panel 110, protecting the display panel 110 from external impact. The edge portion of the cover member 20 can have a curvature portion or a curved surface portion that is bent in the rear direction (e.g.,-Z-axis direction) of the display device 100. Thus, the cover member 20 can be disposed to cover the side area of the display panel 110 disposed on the back surface, so that the display panel 110 can be protected from external impact not only on the front surface but also on the side surface of the display device 100.

The cover member 20 can be formed of a transparent material to overlap with the area that displays an image (e.g., display area AA). For example, the cover member 20 can be made of a transparent plastic material that can transmit an image, reinforced glass made of a transparent glass material, a reinforced plastic, etc., but the present disclosure is not limited thereto.

The display area AA of the display device 100 is an area that displays an image, and an area excluding the display area AA can be referred to as a non-display area NA. The display area AA can be referred to as an ‘active area’ and the non-display area NA can be referred to as a ‘non-active area’. The display area AA and the non-display area NA of the display device 100 can be applied equally to the display panel 110.

A plurality of sub-pixels SP is disposed at the display area AA of the display panel 110, and an image can be displayed using the sub-pixels SP. The area where the sub-pixels SP are disposed to display an image can become a display area AA, and an area excluding the display area AA can become a non-display area NA.

Referring to FIG. 3, at least one sub-pixel SP among a plurality of pixels can include a switching transistor SW, a driving transistor DR, a capacitor Cst, a compensation circuit CC, and an organic light emitting diode OLED.

A first electrode (e.g., a drain electrode) of the switching transistor SW is electrically connected to a data line DL and a second electrode (e.g., a source electrode) thereof is electrically connected to a first node N1. A gate electrode of the switching transistor SW is electrically connected to a gate line GL. The switching transistor SW serves to transmit a data signal supplied through the data line DL to the first node N1 in response to a scan signal supplied through the gate line GL.

The capacitor Cst is electrically connected to the first node N1, charging the voltage applied to the first node N1.

A first electrode (e.g., a drain electrode) of the driving transistor DR receives a high-potential driving voltage EVDD, and a second electrode (e.g., a source electrode) thereof is electrically connected to a first electrode (e.g., an anode) of the organic light emitting diode OLED. The driving transistor DR can serve to control the quantity of driving current flowing to the organic light emitting diode OLED in response to voltage applied to the gate electrode.

The semiconductor layer of the switching transistor SW and/or the driving transistor DR can include silicon such as amorphous silicon (a-Si), polycrystalline silicon (poly-Si), or low-temperature polycrystalline silicon (poly-Si), or can include an oxide semiconductor such as IGZO (indium-gallium-zinc-oxide), etc.

The organic light emitting diode OLED or light emitting device serves to output light corresponding to the driving current. The organic light emitting diode OLED is able to output light corresponding to any one color selected from among red, green, blue, and white.

The organic light emitting diode OLED can include a first electrode, an emission layer disposed on the first electrode, and a second electrode configured to supply a common voltage. The emission layer can be provided to emit light of the same color for each pixel, such as white light, or to emit light of a different color for each sub-pixel SP, such as red, green, or blue light.

The first electrode can function as an anode, and the second electrode can function as a cathode. The organic light emitting diode OLED can be either a top emission diode or a bottom emission diode. The organic light emitting diode OLED can be substantially identical to a light emitting device 135 (e.g., FIG. 4) described below.

A compensation circuit can be provided at a sub-pixel SP to compensate for the threshold voltage of the driving transistor DR, etc. The compensation circuit can be composed of one or more transistors. The compensation circuit can include one or more transistors and capacitors and can be configured in various ways depending on the compensation method. A pixel including the compensation circuit can have various structures such as 3T1C, 4T2C, 5T2C, 6T1C, 6T2C, 7T1C, 7T2C, etc.

Referring to FIG. 4, a structure disposed at the display area AA of the display panel 110 is described. The display panel 110 includes a transistor TR disposed on a substrate 111 of the display area AA, a light emitting device 135 disposed on the transistor TR, and an encapsulation layer 150 disposed on the light emitting device 135.

The substrate 111 functions to support and protect components of the display device 100 disposed on the substrate 111. The substrate 111 can be formed of a flexible plastic material and can have flexible characteristics.

In the display area AA, the substrate 111 can have a multilayer stack structure including a first flexible substrate 1111 and a second flexible substrate 1112, with an interlayer 117 therebetween.

The first flexible substrate 1111 can form the upper surface of the substrate 111, and the second flexible substrate 1112 can form the lower surface of the substrate 111. For example, the first flexible substrate 1111 and the second flexible substrate 1112, including polyimide, can be disposed.

The interlayer 117 can include an inorganic insulating material. For example, the interlayer 117 including an inorganic insulating material can be disposed between the first flexible substrate 1111 including polyimide and the second flexible substrate 1112 including polyimide.

The first flexible substrate 1111 and the second flexible substrate 1112 include polyimide, and due to the characteristics of polyimide, the first flexible substrate 1111 and/or the second flexible substrate 1112 can become charged. A back bias can be formed by such charges, and the formed back bias can affect elements such as transistors TR on the substrate 111.

However, the substrate 111 according to the present disclosure can be configured such that the interlayer 117 including an inorganic insulating material is disposed between the first flexible substrate 1111 and the second flexible substrate 1112, blocking charges in the substrate 111 from moving to the upper portion of the substrate 111 and minimizing the influence of the charges on the transistor TR located on the upper surface of the substrate 111. Thus, the interlayer 117 can prevent the charges from being stored or accumulated in the substrate 111. In other words, an interlayer 117 including an inorganic insulating material can be disposed between the first and second flexible substrates 1111, 1112 to prevent or minimize charge accumulation by blocking the movement of charges toward the transistor TR and other sensitive internal components.

The inorganic insulating material constituting the interlayer 117 can include silicon nitride (SiNx) or silicon oxide (SiOx). For example, when the interlayer 117 includes silicon oxide (SiOx), the interlayer 117 can have a lower rate of transfer of moisture penetrating from the outside than the first flexible substrate 1111 and the second flexible substrate 1112 including polyimide, so that moisture penetrating from the outside can be blocked or minimized from affecting elements on the substrate. In other words, the interlayer 117 can provide dual functions of blocking or minimizing the penetration of external moisture and blocking or minimizing the movement of charges toward the transistor (TR) and other sensitive internal components.

The first flexible substrate 1111 and the second flexible substrate 1112 are bonded to each other via the interlayer 117.

For example, when the interlayer 117 includes silicon oxide (SiOx), adhesion can be enhanced by bonding of oxygen (O) of the interlayer 117 and hydrogen (H) of the first flexible substrate 1111 and the second flexible substrate 1112 including polyimide.

The interlayer 117 can be disposed throughout the entirety of the display area AA between the first flexible substrate 1111 and the second flexible substrate 1112 in the display area AA.

An insulating film 120 can be provided in a multilayer stack structure in the display area AA of the substrate 111. The insulating film 120 can include a first insulating film 121, a second insulating film 122, and a third insulating film 123.

The first insulating film 121 can be referred to as a buffer film and can have the same function as a buffer film in the art. The first insulating film 121 can be disposed on the substrate 111 to protect structures on the substrate 111, which are vulnerable to moisture penetration, from moisture penetrating through the substrate 111 and to flatten or planarize the surface of the substrate 111.

The first insulating film 121 can be a single inorganic film or can be configured such that multiple inorganic films are stacked on top of each other. For example, the first insulating film 121 can include at least one inorganic film of a silicon oxide film (SiOx), a silicon nitride film (SiNx), or a silicon oxynitride film (SiOxNy), or can include a multilayer film in which the inorganic films described above are stacked.

The transistor TR can be disposed on the first insulating film 121. The transistor TR can be the switching transistor SW or the driving transistor DR as described in FIG. 3. The transistor TR can include a gate electrode, a source electrode, a drain electrode, and an active layer. The active layer can include a semiconductor material. The semiconductor material can be composed of a silicon-based semiconductor material or an oxide-based semiconductor material.

The transistor TR disposed in the display area AA can be a transistor TR including a silicon-based semiconductor material or a transistor TR including an oxide-based semiconductor material depending on the function thereof. Transistors TR including different semiconductor materials can be applied per sub-pixel SP.

The second insulating film 122 is disposed on the first insulating film 121. The second insulating film 122 can be disposed in the display area AA, spacing transistors TR including different semiconductor materials apart from each other or preventing short circuit between electrodes. The second insulating film 122 can include an inorganic film, for example, a silicon oxide film (SiOx), a silicon nitride film (SiNx), or a stack of multiple films thereof.

The third insulating film 123 is disposed on the second insulating film 122. The third insulating film 123 can be disposed in the display area AA to insulate between electrodes constituting the transistor TR on the substrate 111 or to insulate the electrodes and the active layer. The third insulating film 123 can be referred to as an interlayer insulating film and can function as an interlayer insulating film in the art.

The third insulating film 123 can include an inorganic material. The inorganic material can include, for example, at least one inorganic film of a silicon oxide film (SiOx), a silicon nitride film (SiNx), or a silicon oxynitride film (SiOxNy), or can include a multilayer film in which the inorganic films described above are stacked.

An organic film 140 can be disposed on the transistor TR or on the insulating film 120 to protect the transistor TR and alleviate a step difference caused by the transistor TR. The organic film 140 can be disposed between structures or elements of the transistor TR and the light emitting device 135 to reduce parasitic capacitance therebetween. The transistor TR can be covered by the organic film 140 or the organic film 140 can be disposed on the insulating film 120 to achieve surface planarization.

The organic film 140 can have a monolayer or multilayer structure made of an organic material. The organic film 140 can include a first organic film 141 and a second organic film 142 on the first organic film 141.

In the display area AA, one electrode of the transistor TR is covered by the first organic film 141 to flatten the upper surface. The first organic film 141 can include an organic material. The organic material can include at least one of an acrylic resin, a phenolic resin, a polyimide resin, an unsaturated polyester resin, a polyamide resin, a benzocyclobutene resin, a polyphenylene resin, or a polyphenylene sulfide resin.

In the display area AA, the transistor TR and the first organic film 141 are covered by the second organic film 142 to flatten or planarize the upper surface. The second organic film 142 can include an organic material. The organic material can include at least one of an acrylic resin, a phenolic resin, a polyimide resin, an unsaturated polyester resin, a polyamide resin, a benzocyclobutene resin, a polyphenylene resin, or a polyphenylene sulfide resin.

In addition to the insulating film 120 described above, various functional organic or inorganic films can be further disposed between the substrate 111 and the organic film 140.

The light emitting device 135 is disposed on the organic film 140 in the display area AA. The light emitting device 135 can be electrically connected to the transistor TR through the organic film 140. The light emitting device 135 includes a first electrode E1, an emission layer EL, and a second electrode E2.

The first electrode E1 can function as an anode. The first electrode E1 can be connected to the transistor TR through the organic film 140.

The first electrode E1 can include a metal material having high reflectivity. For example, the first electrode E1 can include a multilayer structure such as a stack structure of aluminum (Al) and titanium (Ti) (Ti/Al/Ti), a stack structure of aluminum (Al) and ITO (ITO/Al/ITO), an APC (Ag/Pd/Cu) alloy, a stack structure of APC alloy and ITO (ITO/APC/ITO), or a stack structure of silver (Ag) and molybdenum/titanium alloy (Ag/MoTi), or can include a monolayer structure made of any one material or an alloy material of two or more selected from among silver (Ag), aluminum (Al), molybdenum (Mo), gold (Au), magnesium (Mg), calcium (Ca), and barium (Ba). The first electrode E1 can be referred to as a reflective electrode.

The emission layer EL is provided on the first electrode E1. The emission layer EL can include a hole injection layer, a hole transport layer, an organic emission layer, an electron transport layer, and an electron injection layer.

When voltage is applied to the first electrode E1 and the second electrode E2, holes and electrons move to the organic emission layer through the hole injection layer and hole transport layer and the electron injection layer and electron transport layer, respectively, and combine with each other in the organic emission layer, emitting light.

Although the emission layer EL is illustrated as being disposed in the opening area in the drawing, the hole injection layer, hole transport layer, electron transport layer, and electron injection layer constituting the emission layer EL can be disposed commonly on the front surface of the display area AA (e.g., laid down as a common layer across multiple subpixels).

The emission layer EL can be composed of a red emission layer that emits red light, a green emission layer that emits green light, and a blue emission layer that emits blue light. The red emission layer, the green emission layer, and the blue emission layer can be disposed for respective sub-pixels SP on the first electrode E1. A red emission layer can be patterned and disposed in a red sub-pixel, a green emission layer can be patterned and disposed in a green sub-pixel, and a blue emission layer can be patterned and disposed in a blue sub-pixel, but the present disclosure is not necessarily limited thereto, and at least two organic emission layers selected from among a red emission layer, a green emission layer, and a blue emission layer can be stacked and disposed in one sub-pixel SP.

The emission layer EL can be a white emission layer that emits white light. As such, the organic emission layer of the emission layer EL can be a common layer that is commonly disposed in the sub-pixels SP rather than in a pattern form.

As described above, the emission layer EL can be disposed in a tandem structure of two or more stacks. As such, each light emitting device 135 can include a charge generation layer disposed between the stacks. The charge generation layer can be a common layer disposed on the front surface of the display area AA.

The second electrode E2 is provided on the emission layer EL. The second electrode E2 can function as a cathode. The second electrode E2 can be disposed not only in the emissive area of the sub-pixel SP, but also throughout the entirety of the display area AA (e.g., laid down as a common layer across multiple subpixels). The second electrode E2 can be disposed in a pattern form when the display area AA is functionally divided.

The second electrode E2 can be a common layer that is commonly disposed across the sub-pixels SP to apply the same voltage. To this end, the second electrode E2 can be disposed to extend from the display area AA to a portion of the non-display area NA.

The second electrode E2 can be a transparent electrode. The second electrode E2 can include a transparent conductive material (TCO) capable of transmitting light, such as ITO or IZO, or a semi-transmissive conductive material, such as magnesium (Mg), silver (Ag), or an alloy of magnesium (Mg) and silver (Ag). When the second electrode E2 includes a semi-transmissive conductive material, light extraction efficiency can be increased by virtue of microcavity design.

The top emission-type light emitting device 135 was described above. However, the light emitting device 135 of the present disclosure is not limited thereto, and can be provided in a bottom emission type in which light emitted from the emission layer EL is emitted toward the substrate 111. As such, the first electrode E1 can be composed of a transparent or translucent electrode material, and the second electrode E2 can be composed of a reflective electrode material. The transparent or translucent electrode material and the reflective electrode materials can include the materials described above.

A third organic film 143 can be disposed on the second organic film 142 to cover the end of the first electrode E1 of the light emitting device 135. For example, outer edges of the first electrode E1 can be overlapped by parts of the third organic film 143.

The third organic film 143 can be referred to as a bank defining an emissive area.

The third organic film 143 is disposed so that the first electrode E1 of the emissive area is opened (e.g., has an opening area or hole) for each sub-pixel SP and first electrodes E1 between adjacent sub-pixels SP can be electrically insulated from each other. Using a halftone mask, the third organic film 143 can be disposed in a form having not only banks but also spacers between the banks. The spacer can function to support a deposition mask so that the bank and the structure under the bank do not come into contact during deposition of the emission layer EL.

The third organic film 143 can be disposed to extend from the display area AA to a portion of the non-display area NA. The third organic film 143 can be disposed in a pattern form depending on the functional role thereof in the non-display area NA.

The third organic film 143 can include any one organic material selected from among a polyimide resin, an acrylic resin, an epoxy resin, a phenolic resin, and a polyamide resin.

An encapsulation layer 150 is disposed on the light emitting device 135. The encapsulation layer 150 extends from the display area AA and is also disposed on the non-display area NA. The display area AA and the non-display area NA can be covered by the encapsulation layer 150, preventing oxygen or moisture from penetrating structures on the substrate 111, such as the light emitting device 135 and the transistor TR. According to embodiments, other layers such as a capping layer, etc. can be further interposed between the encapsulation layer 150 and the second electrode E2.

The encapsulation layer 150 can have a multilayer structure. The encapsulation layer 150 can be configured such that inorganic and organic films are alternately stacked on top of each other. According to an embodiment of the present disclosure, the encapsulation layer 150 can include a first encapsulation layer 151, a second encapsulation layer 152, and an organic encapsulation layer 154 interposed between the first encapsulation layer 151 and the second encapsulation layer 152. The first and second encapsulation layers 151, 152 can be inorganic encapsulation films. The first encapsulation layer 151 can be disposed adjacent to the light emitting device 135, and the second encapsulation layer 152 can be disposed on the uppermost surface of the encapsulation layer 150.

The first encapsulation layer 151 can be disposed on the entire upper surface of the transistor TR and the light emitting device 135 in the display area AA. The light emitting device 135 can be completely covered by the first encapsulation layer 151 to seal or enclose the light emitting device 135. The first encapsulation layer 151 can be disposed to extend from the display area AA to a portion of the non-display area NA.

The first encapsulation layer 151 can be made of an inorganic insulating material. For example, the first encapsulation layer 151 can include an inorganic insulating material such as silicon oxide, silicon nitride, and/or silicon oxynitride.

The organic encapsulation layer 154 is disposed on the first encapsulation layer 151, and the organic encapsulation layer 154 functions to flatten or planarize the upper surface to minimize cracking that can be caused by step coverage due to structures under the organic encapsulation layer 154.

The organic encapsulation layer 154 can include at least one organic material selected from the group consisting of polyethylene terephthalate, polyethylene naphthalate, polycarbonate, polyimide, polyethylene sulfonate, polyoxymethylene, polyarylate, and hexamethyldisiloxane.

The second encapsulation layer 152 can be disposed on the organic encapsulation layer 154. The second encapsulation layer 152 can be disposed to extend from the display area AA to a portion of the non-display area NA.

The second encapsulation layer 152 can be made of an inorganic insulating material. For example, the second encapsulation layer 152 can include an inorganic insulating material such as silicon oxide, silicon nitride, and/or silicon oxynitride.

A back plate 31 can be disposed on the back surface of the substrate 111. The back plate 31 enables the substrate 111 to remain flat and serves to support the substrate 111. The back plate 31 can be attached to the back surface of the substrate 111 using an adhesive or the like. The back plate 31 is disposed to extend from the display area AA to the non-display area NA.

The back plate 31 can be made of a rigid plastic thin film. For example, the back plate 31 can include any one selected from among polyethylene terephthalate (PET), polyimide (PI), and polyethylene naphthalate (PEN).

The non-display area NA can correspond to an area surrounding the display area AA that displays an image, as shown in FIG. 2. The non-display area NA can include a driving circuit area 109 for driving a plurality of sub-pixels SP, and at least one driving chip 107 can be disposed in the driving circuit area 109.

The driving chip 107 can be provided in the form of a driver integrated circuit (D-IC). The driving chip 107 can be mounted in the driving circuit area 109 beyond the bending area BA including the bending line BL in the non-display area NA of the display panel 110 using a chip-on-panel (COP) method. The bending area BA is disposed in the area between the driving chip 107 and the display area AA. The driving chip 107 can function as a data driving circuit.

The driving circuit area 109 can further include a gate driving circuit disposed in the non-display area NA in the form of a gate-in-panel (GIP).

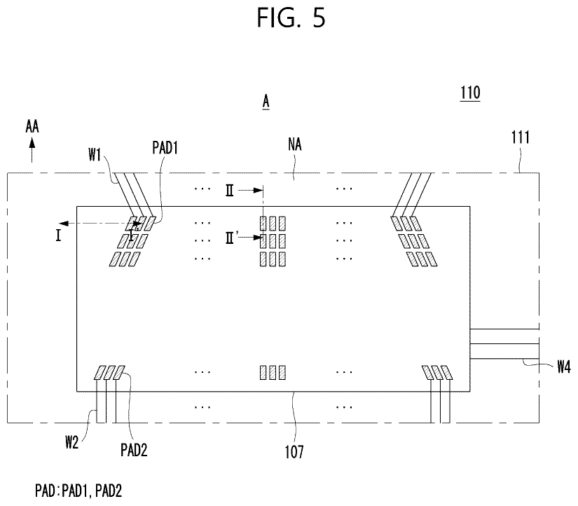

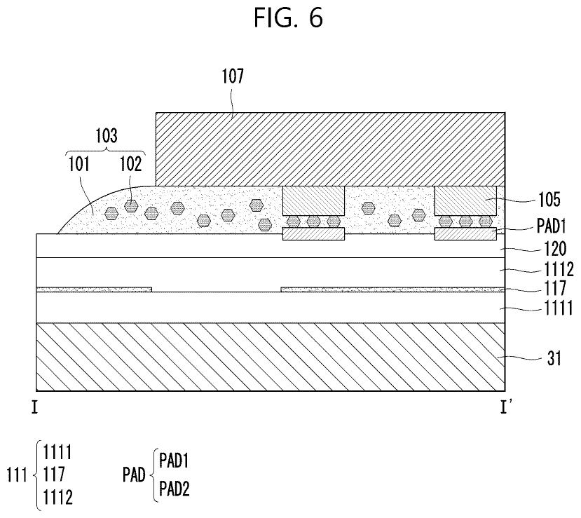

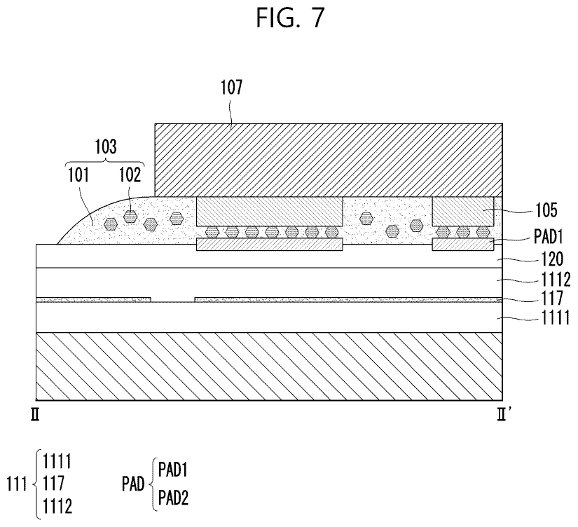

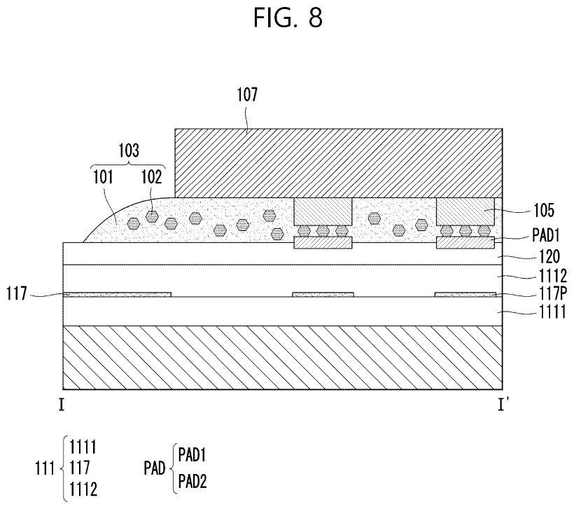

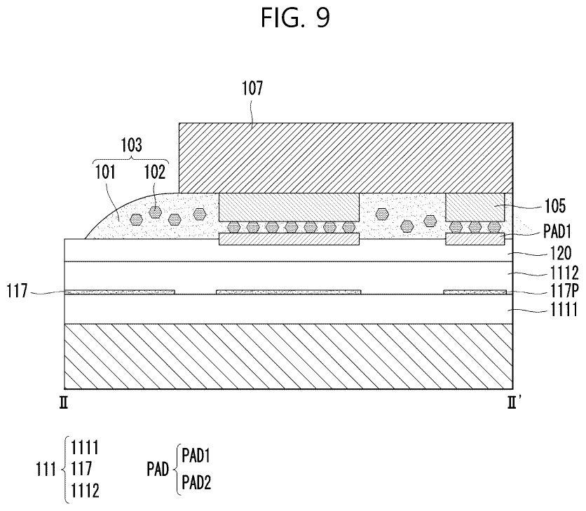

FIG. 5 is an enlarged partial plan view of portion A of FIG. 2 according to one embodiment, FIGS. 6 and 8 are cross-sectional views taken along line I-I′ of FIG. 5 according to embodiments, and FIGS. 7 and 9 are cross-sectional views taken along line II-II′ of FIG. 5 according to embodiments.

Referring to FIG. 5, a structure disposed in the non-display area NA of the display panel 110 is described. The display panel 110 can further include a pad PAD on the substrate 111 that is electrically connected to the driving chip 107 mounted in the non-display area NA, and multiple wires W1, W2, W4 disposed in the non-display area NA and electrically connected to the pad PAD or the driving chip 107. As such, a plurality of pads PAD can be disposed and can include first pads PAD1 and second pads PAD2.

The driving chip 107 can be disposed in the non-display area NA of the display panel 110 using a COP (chip-on-panel) method. The COP method involves attaching the driving chip 107 in the form of a driver IC to pads PAD of the substrate 111 using an anisotropic conductive film (ACF) 103 shown in FIG. 6. For example, the anisotropic conductive film (ACF) 103 can provide both a mechanical adhesive bond and an electrical interconnection between components. The AFC film can exhibit anisotropic conductivity such as being configured to conduct electricity vertically (e.g., Z-axis) through conductive particles when compressed, while the spacing of these particles can ensure electrical insulation horizontally (e.g., X-Y plane) to prevent short circuits between adjacent terminals.

The driving chip 107 receives a signal for driving the display panel 110 from the outside and provides or transmits the signal to the display panel 110. The driving chip 107 can serve to transmit a data signal to the data line DL of the display area AA. The driving chip 107 can also receive a signal from the display area AA of the display panel 110.

The driving chip 107 is electrically connected to an external signal and display panel 110 through the second pads PAD2 and the first pads PAD1. Specifically, the driving chip 107 receives a signal from the outside through the second wires W2 and the second pads PAD2. The driving chip 107 can serve to transmit a signal received from the outside to the display area AA through the first pads PAD1 and the first wires W1.

The first pads PAD1 are disposed relatively closer to the display area AA than the second pads PAD2. The first pads PAD1 can be provided in multiple rows. A plurality of first pads PAD1 disposed in one row is spaced apart from each other. For example, the first pads PAD1 can be disposed in three rows, but the present disclosure is not limited thereto, and the first pads PAD1 can be provided in two or fewer rows or in four or more rows. The first pads PAD1 can have short sides and long sides. Also, some groups of pads can be disposed along a diagonal direction, while other groups of pads can be disposed along a straight column direction, but embodiments are not limited thereto.

The first pads PAD1 are connected to the first wires W1. The first pads PAD1 can be connected to respective first wires W1. The first wires W1 can be connected to the data lines DL of the display area AA.

The first pads PAD1 can be disposed on the same layer as any one of a plurality of adjacent wires, for example, the first wires W1, the second wires W2, and the fourth wires W4. The first pads PAD1 can be made of the same material as any one of the adjacent wires, for example, the first wires W1, the second wires W2, and the fourth wires W4.

The first pads PAD1 are connected to the driving chip 107 through the anisotropic conductive film 103 (e.g., FIG. 6). As such, bumps 105 (e.g., FIG. 6) disposed on the driving chip 107 and the first pads PAD1 are electrically connected through the anisotropic conductive film 103 (e.g., FIG. 6).

The first pads PAD1 can be connected to respective bumps 105. Accordingly, the first pads PAD1 can receive voltages and/or signals applied to the driving chip 107 through the bumps 105.

As shown in FIG. 5, the second pads PAD2 can be provided in a single row. The second pads PAD2 disposed in one row are spaced apart from each other. For example, the second pads PAD2 can be disposed in one row, but the present disclosure is not limited thereto, and the second pads PAD2 can be provided in two or more rows. The second pads PAD2 can have short sides and long sides.

The second pads PAD2 are connected to the second wires W2. The second pads PAD2 can be connected to respective second wires W2. The second wires W2 can be connected to an external circuit board.

The second pads PAD2 can be disposed on the same layer as any one of the first wires W1, the second wires W2, and the fourth wires W4. The second pads PAD2 can be made of the same material as any one of the first wires W1, the second wires W2, and the fourth wires W4.

The second pads PAD2 are connected to the driving chip 107 through the anisotropic conductive film 103. As such, the bumps 105 disposed on the driving chip 107 and the second pads PAD2 are electrically connected. The second pads PAD2 can be connected to respective bumps 105. Accordingly, the second pads PAD2 can provide external voltages and/or signals to the driving chip 107 through the bumps 105.

The first pads PAD1 and the second pads PAD2 can have the same stack structure.

The first wires W1 can serve to connect the first pads PAD1 and some of the signal lines (e.g., data line DL). The first wires W1 and the fourth wires W4 can be disposed on the same layer. The first wires W1 and the fourth wires W4 can be made of the same material.

The second wires W2 are disposed at one end of the display panel 110 and serve to connect the second pads PAD2 and an external circuit board. For example, the external circuit board can be a flexible printed circuit board (FPC). The second wires W2 can be arranged in a direction intersecting the long side of the driving chip 107.

The second wires W2 and the first wires W1 can be disposed on the same layer. The second wires W2 and the first wires W1 can be made of the same material.

The fourth wires W4 can be arranged in a direction intersecting the short side of the driving chip 107. The fourth wires W4 can be multiplexer driving lines or test lines. The fourth wires W4 can be disposed on the same layer as the first wires W1 or the second wires W2. The fourth wires W4 and the first wires W1 or the second wires W2 can be made of the same material.

Referring to FIGS. 6 and 7, the anisotropic conductive film 103 is disposed between the driving chip 107 and the pads PAD.

The anisotropic conductive film 103 includes an adhesive member 101 and a plurality of conductive balls 102. The adhesive member 101 enables the driving chip 107 to be attached to the display panel 110, and the conductive balls 102 are irregularly distributed in the adhesive member 101 to electrically connect the driving chip 107 to the first pads PAD1.

The conductive balls 102 can be particles using conductive particles alone, particles in which polymer resin particles are coated with a metal layer, or particles in which an insulating resin is applied onto the surface of the conductive particles or particles coated with a metal layer. For example, the metal layer can be made of a material such as nickel (Ni), gold (Au), etc.

The substrate 111 of the non-display area NA is in a form in which the substrate 111 of the display area AA extends to the non-display area NA and is formed of a flexible plastic material, so that it can have flexible characteristics.

The substrate 111 of the non-display area NA can have a multilayer stack structure including a first flexible substrate 1111 and a second flexible substrate 1112, with an interlayer 117 therebetween. Also, according to an embodiment, the first flexible substrate 1111, the second flexible substrate 1112, and the interlayer 117 can be referred to as a first flexible insulating film 1111, a second flexible insulating film 1112, and an insulating interlayer 117, but embodiments are not limited thereto.

The first flexible substrate 1111 can form the upper surface of the substrate 111, and the second flexible substrate 1112 can form the lower surface of the substrate 111. The first flexible substrate 1111 and the second flexible substrate 1112, including polyimide, can be disposed.

The interlayer 117 disposed between the first flexible substrate 1111 and the second flexible substrate 1112 can include an inorganic insulating material. For example, the interlayer 117 including an inorganic insulating material can be disposed between the first flexible substrate 1111 including polyimide and the second flexible substrate 1112 including polyimide.

The interlayer 117 can be disposed so that it does not overlap with an edge portion of at least one side of the driving chip 107 in the non-display area NA. The interlayer 117 may not overlap the edge of the lower surface of the driving chip 107. The interlayer 117 is disposed inside the substrate 111 so that it does not overlap with the four sides of the lower surface of the driving chip 107.

Specifically, the interlayer 117 can be disposed so that it does not overlap with an area between an edge of at least one side of the driving chip 107 and a pad PAD disposed at the outermost end among a plurality of pads PAD. Also, the interlayer 117 can be disposed so that it does not over overlap with an area between an edge of at least one side of the driving chip 107 and a bump 105 disposed at the outermost end among a plurality of bumps 105. For example, the interlayer 117 can be positioned so that it does not extend into the region between a lateral edge of the driving chip 107 and the outermost edges of the corresponding plurality of pads PAD or bumps 105. For example, the interlayer 117 can have an opening that corresponds to the area between an edge of the driving chip 107 and an outer PAD and its corresponding bump.

An inorganic insulating material constituting the interlayer 117 can include silicon nitride (SiNx) or silicon oxide (SiOx).

For example, when the interlayer 117 includes silicon oxide (SiOx), the interlayer 117 can have a lower rate of transfer of moisture penetrating from the outside than the first flexible substrate 1111 and the second flexible substrate 1112 including polyimide, so that moisture penetrating from the outside can be blocked or minimized from affecting elements on the substrate.

When the interlayer 117 includes silicon oxide (SiOx), adhesion can be enhanced by bonding of oxygen (O) of the interlayer 117 and hydrogen (H) of the first flexible substrate 1111 and the second flexible substrate 1112 including polyimide.

Referring to FIGS. 8 and 9, the interlayer 117 can include a plurality of interlayer patterns 117P disposed between the first flexible substrate 1111 and the second flexible substrate 1112 in an area where the driving chip 107 is mounted.

The interlayer patterns 117P can be disposed between the first flexible substrate 1111 and the second flexible substrate 1112 to overlap with a plurality of pads PADs disposed on the substrate 111 corresponding to the driving chip 107 and not overlap with gaps between the pads PADs. For example, the interlayer patterns 117P can be disposed between the first and second flexible substrates 1111, 1112 to align with and overlap the plurality of pads (PADs) while avoiding the gaps between the pads. The interlayer patterns 117P can correspond to the pads on a one to one basis, but embodiments are not limited thereto.

Also, the interlayer patterns 117P can be disposed between the first flexible substrate 1111 and the second flexible substrate 1112 to overlap with a plurality of bumps 105 of the driving chip 107 and not to overlap with gaps between the bumps 105.

The interlayer patterns 117P can be disposed to correspond to respective bumps 105, or can be disposed to correspond to respective pads PAD.

When the first flexible substrate 1111 and the second flexible substrate 1112 include polyimide, due to the characteristics of polyimide, the first flexible substrate 1111 and/or the second flexible substrate 1112 can become charged, and such charges can move to the outside of the substrate 111 or to the metal.

The substrate 111 according to the present disclosure can be configured such that the interlayer 117 or interlayer patterns 117P including a silicon oxide film are disposed between the first flexible substrate 1111 and the second flexible substrate 1112 inside the substrate 111 to correspond to the bumps 105 or pads PAD of the driving chip 107, blocking charges in the substrate 111 from moving to the metal pads PAD or to the outside of the substrate 111.

Specifically, by bonding of oxygen in the interlayer 117 or interlayer patterns 117P including a silicon oxide film with charges in the first flexible substrate 1111 or the second flexible substrate 1112, it is possible to prevent the inflow of charges into the driving chip 107 and minimize deterioration in reliability of the driving chip 107 due to such charges.

The interlayer patterns 117P can be disposed on the same layer as the interlayer 117 provided inside the substrate 111 in the display area, or can be formed of the same material as the interlayer 117.

The interlayer patterns 117P can be spaced apart from each other so that the first flexible substrate 1111 is exposed between the interlayer patterns 117P. The first flexible substrate 1111 and the second flexible substrate 1112 can be in direct contact with each other between the interlayer patterns 117P. For example, the interlayer patterns 117P can be spaced apart from one another, defining regions where the first flexible substrate 1111 and the second flexible substrate 1112 can be in direct contact with each other.

In an area where the interlayer 117 and the interlayer patterns 117P are disposed, the first flexible substrate 1111 and the second flexible substrate 1112 are connected through the interlayer 117 and the interlayer patterns 117P, and in an area where the interlayer 117 and the interlayer patterns 117P are not disposed, the first flexible substrate 1111 and the second flexible substrate 1112 are directly connected to each other.

Specifically, at the outside of the driving chip 107, the first flexible substrate 1111 and the second flexible substrate 1112 are connected through the interlayer 117, and in the area overlapping with at least one edge portion of the lower surface of the driving chip 107, the first flexible substrate 1111 and the second flexible substrate 1112 are in direct contact with each other.

The interlayer 117 and the interlayer patterns 117P are not disposed on the edge portion of the driving chip 107 so as not to overlap with the lower surface of one edge of the driving chip 107 in the area where the driving chip 107 is disposed and the pad PAD or the bump 105 disposed at the outermost end among the pads PAD or the bumps 105. For example, the interlayer 117 can have an opening that overlaps with or corresponds to the edge portion of the driving chip 107.

Since the driving chip 107 is electrically connected to the first pads PAD1 through the conductive balls 102, pressure is applied when mounting the driving chip 107 so that the conductive balls 102 come into contact with the bumps 105 and the first pads PAD1.

Since the interlayer 117 and the interlayer patterns 117P do not overlap with the four sides or perimeter of the lower surface of the driving chip 107, film lifting of the interlayer 117 inside the substrate 111 due to bonding pressure or pressing applied to the edge portion of the driving chip 107 during mounting of the driving chip 107 can be reduced, and cracking at the edge portion of the driving chip 107 can be prevented. In other words, positioning the interlayer 117 and its patterns 117P away from the perimeter of the driving chip 107 can reduce the risk of film lifting or pealing within the substrate 111 and prevent cracking at the edge of the driving chip, which can otherwise be caused by the bonding pressure applied during the mounting process (e.g., a type of flexible cushioning area can be provided around the driving chip).

The display device 100 according to the present disclosure can be configured such that the interlayer 117 and the interlayer patterns 117P are disposed so as not to overlap with the four sides of the lower surface of the driving chip 107, preventing film lifting and cracking, thereby reducing moisture penetration and deformation of the display panel 110, resulting in improved robustness and durability.

The first and second flexible substrates 1111, 1112 corresponding to the edge region of the driving chip 107 can be in direct contact with each other.

An additional interlayer pattern 117P can be disposed in the substrate 111 corresponding to the area between the edge portion of the driving chip 107 and the bump. As such, the width and size of the additional interlayer pattern 117P can be smaller than the width and size of the interlayer patterns 117P disposed corresponding to the bumps 105 or pads PAD.

As such, a plurality of additional interlayer patterns 117P can be disposed inside the substrate 111. The gap between the interlayer patterns 117P corresponding to the bumps 105 or pads PAD can be greater than the gap between the additional interlayer patterns 117P disposed corresponding to the area between the edge portion of the driving chip 107 and the bumps 105.

The additional interlayer patterns 117P are not disposed in the area corresponding to the edge portion of the driving chip 107, thereby reducing film lifting of the interlayer 117 inside the substrate 111 due to bonding pressure or pressing applied to the edge portion of the driving chip 107 during mounting of the driving chip 107 (e.g., providing an area around the driving chip that has more give or cushioning).

The additional interlayer patterns 117P can serve to disperse stress due to bonding pressure at the edge portion of the driving chip 107 and can change the cracking path inside the substrate 111, so that crack propagation to the inside can be blocked or minimized even when cracking occurs.

In the display device 100 according to an embodiment of the present disclosure, the interlayer 117 is not disposed along the edge of the lower surface of the driving chip 107 and a plurality of interlayer patterns 117P are disposed in the other areas, minimizing cracking and preventing crack propagation and moisture penetration, thereby improving reliability.

The display device 100 according to an embodiment of the present disclosure is capable of minimizing occurrence of defects in the display device, thus reducing energy consumed to produce the display device, and reducing the use of hazardous production materials or regulated materials, thereby facilitating recycling and implementation of an eco-friendly display device.

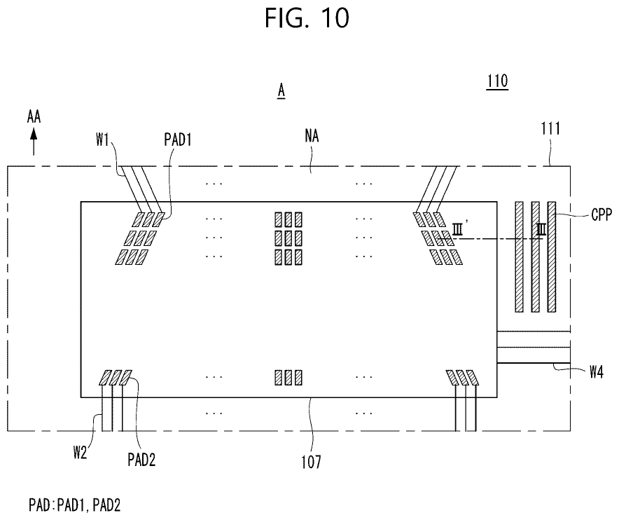

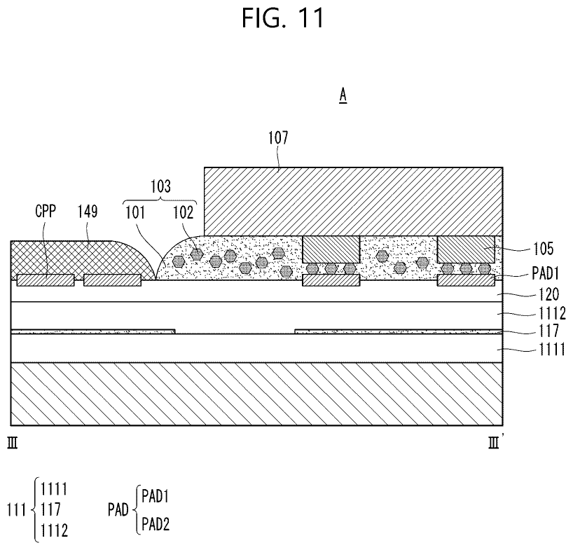

Referring to FIGS. 10 and 11, the display device 100 according to embodiments of the present disclosure can further include a plurality of crack prevention patterns CPP disposed in the non-display area NA of the substrate 111.

The crack prevention patterns CPP are spared apart from the driving chip 107 and the anisotropic conductive film 103 and are disposed on the insulating film 120. The crack prevention patterns CPP are disposed on the insulating film 120 to overlap with the interlayer 117 in an area adjacent to the driving chip 107.

Here, the insulating film 120 can have the same stack structure as the insulating film 120 disposed in the display area AA or can have a structure in which at least one layer of the configuration of the insulating film 120 disposed in the display area AA is omitted.

The crack prevention patterns CPP can be spaced apart from the driving chip 107 in a direction parallel to the short side of the driving chip 107 and can be disposed in the non-display area NA of the display panel 110. The length of the long side of the crack prevention patterns CPP can be less than the length of the short side of the driving chip 107, but embodiments are not limited thereto.

The crack prevention patterns CPP overlap with the interlayer 117, are spaced apart from the first pads PAD1 and the second pads PAD2 so as not to overlap with the first pads PAD1 and the second pads PAD2, and are spaced apart from an edge of one short side of the driving chip 107. The crack prevention patterns CPP can be provided in the form of a relief pattern based on the upper surface of the substrate 111 of the display panel 110.

As described above, since the driving chip 107 in the form of an IC is attached to the substrate 111 using a COP method, a pressure mark test or the like is performed to check the connection status of the driving chip 107, and high pressure can be applied when attaching the driving chip 107 to the substrate 111 to prevent poor connection of the driving chip 107. The crack prevention patterns CPP according to an embodiment of the present disclosure are disposed adjacent to the short side of the driving chip 107 where stress is likely to occur due to pressure, etc. when the driving chip 107 is mounted, thereby reducing deformation of the display panel 110 due to stress when the driving chip 107 is mounted or cracking due to interference of the driving chip 107. In other words, to prevent panel deformation and cracking, crack prevention patterns CPP can be disposed adjacent to the edge of the driving chip 107, where stress is often concentrated during the high-pressure mounting process.

The crack prevention patterns CPP according to an embodiment of the present disclosure can serve to prevent cracking around the driving chip 107 when the driving chip 107 is bonded, thereby preventing moisture penetration due to cracks and film lifting or pealing in the surrounding insulating film due to moisture penetration, and also preventing cracking in the surrounding insulating film due to film lifting.

The crack prevention patterns CPP according to an embodiment of the present disclosure can serve to prevent cracking in the insulating film disposed around the driving chip 107, thereby preventing corrosion or cracking in surrounding pads PAD1, PAD2 or multiple wires W1, W2, W4 due to moisture penetration, etc. caused by cracks in the insulating film.

The crack prevention patterns CPP according to an embodiment of the present disclosure can serve to prevent cracking and moisture penetration, thereby reducing deformation of the display panel 110.

The crack prevention patterns CPP can include a metal. When the crack prevention patterns CPP including a metal are disposed, rigidity can be ensured, thus supporting pressure that is applied when mounting the driving chip 107, thereby more effectively preventing cracking around the driving chip 107 and reducing deformation of the display panel 110.

The crack prevention patterns can include the same material as the source/drain electrode or gate electrode constituting the transistor TR of the display area AA. The crack prevention patterns can be disposed on the same layer as the pads PAD of the non-display area NA or can include the same material. The crack prevention patterns CPP can be disposed on the same layer as any one of the wires W1, W2, W4 disposed in the non-display area NA, or can be made of the same material.

In this way, when the crack prevention patterns CPP are disposed by the same process as the process of forming electrodes disposed in the display area AA or pads PAD or wires W1, W2, W4 of the non-display area NA, the number of processes for manufacturing the display device can be reduced, thus reducing energy consumed during the manufacturing process and reducing generation of greenhouse gases, thereby achieving ESG (environmental/social/governance) goals.

The crack prevention patterns CPP can be disposed using electrode or wire processes, but are floating so that voltages or signals are not applied. The crack prevention patterns CPP can be covered with an insulating material 149. The insulating material 149 can be disposed on the same layer as at least one of the stacked layers constituting the organic film 140 (e.g., FIG. 4) disposed in the display area AA or can include the same material.

Features of various embodiments of the present disclosure can be partially or overall coupled to or combined with each other, and can be variously inter-operated with each other and driven technically. The embodiments of the present disclosure can be carried out independently from each other, or can be carried out together in a co-dependent relationship.

As is apparent from the foregoing, according to embodiments of the present disclosure, an interlayer or interlayer patterns can be provided between a first flexible substrate and a second flexible substrate to overlap with bumps or pads of a driving chip, preventing charge inflow into the driving chip and alleviating deterioration in reliability of the element due to accumulated charges.

According to embodiments of the present disclosure, the interlayer and the interlayer patterns can be disposed between the first flexible substrate and the second flexible substrate so as not to overlap with an edge portion of at least one side of the driving chip, minimizing cracking and preventing crack propagation and moisture penetration, thereby improving reliability.

According to embodiments of the present disclosure, the interlayer can be disposed between the first flexible substrate and the second flexible substrate so as not to overlap with four sides of the lower surface of the driving chip, reducing lifting defects of the substrate and deformation of the display panel, thereby providing a robust display device and improving durability of the display device.

The display device according to embodiments of the present disclosure is provided using the same process, occurrence of defects in the display device can be minimized, reducing energy consumed to produce the display device, and the use of hazardous production materials or regulated materials can be reduced, facilitating recycling and implementation of an eco-friendly display device.

The embodiments of the present disclosure have been mainly described for illustrative purposes rather than to limit the present disclosure, and the present disclosure described above is not limited to the embodiments and the attached drawings, and the features, structures, effects, etc. exemplified in individual embodiments can be implemented by combination or modification. Accordingly, such combinations and modifications should be construed as being within the scope of the present disclosure.

What is claimed IS:

1. A display device, comprising:
a substrate having a display area and a non-display area and including a first flexible substrate, an interlayer, and a second flexible substrate;
a transistor and a light emitting device in the display area; and
a driving chip in the non-display area,
wherein the interlayer is disposed between the first flexible substrate and the second flexible substrate without overlapping with an edge portion of at least one side of the driving chip.

2. The display device according to claim 1, wherein the interlayer is disposed inside the substrate and does not overlap with four sides of a lower surface of the driving chip.

3. The display device according to claim 1, further comprising:
a pad disposed on the substrate in an area overlapping with the driving chip; and
a bump disposed under the driving chip and corresponding to the pad,
wherein the interlayer does not overlap with an area between an edge of at least one side of the driving chip and an outermost pad among a plurality of pads, or
the interlayer does not overlap with an area between an edge of at least one side of the driving chip and an outermost bump among a plurality of bumps.

4. The display device according to claim 1, wherein the interlayer includes a plurality of interlayer patterns disposed between the first flexible substrate and the second flexible substrate at an area where the driving chip is mounted.

5. The display device according to claim 4, wherein:
the plurality of interlayer patterns are disposed between the first flexible substrate and the second flexible substrate, and
the plurality of interlayer patterns overlap with a plurality of bumps of the driving chip and do not overlap with gaps between the plurality of bumps.

6. The display device according to claim 4, wherein:
the plurality of interlayer patterns are disposed between the first flexible substrate and the second flexible substrate, and
the plurality of interlayer patterns overlap with a plurality of pads disposed on the substrate corresponding to the driving chip and do not overlap with gaps between the plurality of pads.

7. The display device according to claim 4, wherein the interlayer or the plurality of interlayer patterns include silicon oxide.

8. The display device according to claim 1, wherein the first flexible substrate and the second flexible substrate are connected to each other through the interlayer at an area outside of the driving chip and are in direct contact with each other at an area overlapping with at least one edge portion of a lower surface of the driving chip.

9. The display device according to claim 1, further comprising:
an insulating film including a plurality of layers stacked on top of each other at the non-display area of the substrate;
an anisotropic conductive film disposed between the driving chip and the insulating film; and
a plurality of crack prevention patterns disposed on the insulating film, the plurality of crack prevention patterns being spaced apart from the driving chip and the anisotropic conductive film.

10. The display device according to claim 9, wherein the plurality of crack prevention patterns overlap with the interlayer.

11. The display device according to claim 9, wherein the plurality of crack prevention patterns are a relief pattern including metal.

12. The display device according to claim 9, wherein the plurality of crack prevention patterns included a same material as a material in a source/drain electrode or a gate electrode of the transistor in the display area.

13. The display device according to claim 9, wherein the plurality of crack prevention patterns are disposed at a same layer as a pad disposed on the substrate, or the plurality of crack prevention patterns include a same material as the pad.

14. The display device according to claim 9, further comprising:
a first pad disposed in a direction toward the display area at an area where the driving chip is disposed, and
a second pad disposed in a direction opposite the direction toward the display area and facing the first pad at the area where the driving chip is disposed,
wherein the plurality of crack prevention patterns overlap with the interlayer, are spaced apart from the first pad and the second pad, and are spaced apart from an edge of one short side of the driving chip.

15. The display device according to claim 1, wherein the transistor disposed in the display area includes an oxide semiconductor.

16. A display device, comprising:
a plurality of subpixels configured to display an image;
a driving chip spaced apart from the plurality of subpixels;
a first flexible layer disposed under the plurality of subpixels and the driving chip;
a second flexible layer disposed on the first flexible layer; and
an interlayer disposed between the first flexible layer and the second flexible layer,
wherein the interlayer includes at least one opening corresponding to an edge of the driving chip.

17. The display device of claim 16, wherein the at least one opening in the interlayer is a single, continuous opening that corresponds to a full perimeter of the driving chip.

18. The display device of claim 16, further comprising:
a plurality of pads disposed on the second flexible layer and configured to electrically connect to the driving chip,
wherein the at least one opening in the interlayer extends from the edge of the driving chip to an edge of an outermost pad among the plurality of pads.

19. The display device of claim 16, further comprising:
a plurality of crack prevention patterns disposed adjacent to the driving chip, the plurality of crack prevention patterns including a metal material.

20. The display device of claim 16, further comprising:
a plurality of pads disposed on the second flexible layer and configured to electrically connect to the driving chip,
wherein the interlayer includes a plurality of openings corresponding to a plurality of gaps between the plurality of pads.
